(19) United States
(12) Patent Application Publication
(10) Pub. No.: US 2026/0191103 A1
(43) Pub. Date: Jul. 2, 2026

(54) SEMICONDUCTOR DEVICE AND METHOD OF FABRICATING THE SAME

(71) Applicant: Samsung Electronics Co., Ltd., Suwon-si (KR)

(72) Inventors: Sungmin SON, Suwon-si (KR); Minho JANG, Suwon-si (KR); Jihyun KWAK, Suwon-si (KR); Chang Kyu LEE, Suwon-si (KR); Yongkun JO, Suwon-si (KR)

(73) Assignee: Samsung Electronics Co., Ltd., Suwon-si (KR)

(21) Appl. No.: 19/384,288

(22) Filed: Nov. 10, 2025

(30) Foreign Application Priority Data
Dec. 30, 2024 (KR) 10-2024-0200098

(51) Int. Cl. H01L 23/00; H01L 23/48; H01L 25/065

(52) U.S. Cl. CPC H10W 90/00; H10W 20/20; H10W 72/923; H10W 72/926; H10W 72/936; H10W 90/26; H10W 90/297; H10W 90/792

(57) ABSTRACT

Disclosed are semiconductor devices and their fabrication methods. The semiconductor device includes first and second semiconductor chips. The first semiconductor chip includes a first dielectric layer on a first semiconductor substrate, a first pad part exposed on a top surface of the first dielectric layer, a first via part extending from a bottom surface of the first pad part and coupled to the first semiconductor substrate, a first spacer pattern between the first dielectric layer and the first pad part, a first shield line horizontally spaced apart from the first pad part and extending into the first dielectric layer from the top surface of the first dielectric layer, and a second spacer pattern between the first dielectric layer and the first shield line. The first and second pad parts are in direct contact with each other to constitute a single unitary piece.

### CROSS-REFERENCE TO RELATED APPLICATION

This application claims priority under 35 U.S.C § 119 to Korean Patent Application No. 10-2024-0200098 filed on Dec. 30, 2024 in the Korean Intellectual Property Office, the disclosure of which is hereby incorporated by reference in its entirety.

### BACKGROUND

The present inventive concepts relate to semiconductor devices and methods of fabricating the same, and more particularly, to semiconductor devices including an image sensor and methods of fabricating the same.

An image sensor is a semiconductor device to transforms optical images into electrical signals. An image sensor can be classified into a charge coupled device (CCD) type and a complementary metal oxide semiconductor (CMOS) type. A CMOS type image sensor is abbreviated to CIS (CMOS image sensor). The CIS may include a plurality of two-dimensionally arranged pixels. Each of the pixels includes a photodiode. The photodiode may serve to convert incident light into electrical signals.

Recent advances in computer and communication industries have led to strong demands in high performances image sensors in various consumer electronic devices such as digital cameras, camcorders, PCSs (Personal Communication Systems), game devices, security cameras, medical micro cameras, etc. A plurality of image sensors have recently been used in portable electronic devices, and thus the plurality of image sensors may be integrated and utilized in the devices.

In the semiconductor industry, high capacity, thinness, and compactness of semiconductor devices and electronic products using the same have been demanded and thus various package techniques have been suggested. One approach of the various package techniques is a packaging technique which vertically stacks a plurality of semiconductor chips to achieve a high density chip stacking. This packaging technique may have an advantage capable of integrating semiconductor chips having various functions on a small area than a conventional package consisting of one semiconductor chip.

### SUMMARY

Some embodiments of the present inventive concepts provide semiconductor devices with increased integration and methods of fabricating the same.

Some embodiments of the present inventive concepts provide methods of fabricating a semiconductor device whose process unit price may be reduced and semiconductor devices fabricated by the same.

Some embodiments of the present inventive concepts provide methods of fabricating a semiconductor device whose manufacturing cost may be reduced and semiconductor devices fabricated by the same.

The object of the present inventive concepts is not limited to the mentioned above, and other objects which have not been mentioned above will be clearly understood to those skilled in the art from the following description.

According to some embodiments of the present inventive concepts, a semiconductor device may include a first semiconductor chip; and a second semiconductor chip on the first semiconductor chip. The first semiconductor chip may include a first semiconductor substrate; a first dielectric layer on the first semiconductor substrate; a first pad part exposed on a top surface of the first dielectric layer; a first via part extending from a bottom surface of the first pad part and is coupled to the first semiconductor substrate, the first via part having a width less than a width of the first pad part; a first spacer pattern between the first dielectric layer, a lateral surface of the first pad part, and the bottom surface of the first pad part; a first shield line horizontally spaced apart from the first pad part and extending into the first dielectric layer from the top surface of the first dielectric layer; and a second spacer pattern between the first dielectric layer, a lateral surface of the first shield line, and a bottom surface of the first shield line. On a contact surface between the first semiconductor chip and the second semiconductor chip, the first pad part of the first semiconductor chip and a second pad part of the second semiconductor chip may be in direct contact with each other to constitute a single unitary piece.

According to some embodiments of the present inventive concepts, a semiconductor device may include a first semiconductor chip; a second semiconductor chip on the first semiconductor chip; a color filter array on the second semiconductor chip; and a microlens array on the color filter array. The first semiconductor chip may include a first dielectric layer on a top surface of the first semiconductor chip; a first pad part exposed on a top surface of the first dielectric layer; a first via part extending into the first dielectric layer from a bottom surface of the first pad part; a first shield line horizontally spaced apart from the first pad part and extending into the first dielectric layer from the top surface of the first dielectric layer; and a first spacer pattern covering a lateral surface of the first shield line and a bottom surface of the first shield line. The second semiconductor chip may include a second dielectric layer on a bottom surface of the second semiconductor chip; a second pad part exposed on a bottom surface of the second dielectric layer; a second shield line horizontally spaced apart from the second pad part and extending into the second dielectric layer from the bottom surface of the second dielectric layer; and a second spacer pattern covering a lateral surface of the second shield line and a top surface of the second shield line. On a contact surface between the first semiconductor chip and the second semiconductor chip, the first pad part of the first semiconductor chip and the second pad part of the second semiconductor chip may be in direct contact with each other to constitute a single unitary piece.

According to some embodiments of the present inventive concepts, a method of fabricating a semiconductor device may include sequentially stacking a first dielectric layer and a second dielectric layer on a semiconductor substrate; allowing the second dielectric layer and the first dielectric layer to undergo a first patterning process to define a first hole and a trench, a bottom surface of the first hole and a bottom surface of the trench being at a level higher than a level of a bottom surface of the first dielectric layer; forming a spacer layer covering a top surface of the second dielectric layer, an inner lateral surface of the first hole, the bottom surface of the first hole, an inner lateral surface of the trench, and the bottom surface of the trench; forming on the spacer layer a sacrificial layer filling the first hole and the trench and covering the top surface of the second dielectric layer; allowing the sacrificial layer, the spacer layer, and the first dielectric layer to undergo a second patterning process to define a second hole, the second hole being inside the first hole; removing the sacrificial layer; forming, on the spacer layer, a conductive layer filling the first hole, the second hole, and the trench and covers the top surface of the second dielectric layer; and allowing the conductive layer to undergo a thinning process to expose the top surface of the second dielectric layer. A wavelength of a light source used in the first patterning process may be greater than a wavelength of a light source used in the second patterning process.

According to some embodiments of the present inventive concepts, a method of fabricating a semiconductor device may include forming a first semiconductor chip using a first method, the first method including sequentially stacking a first dielectric layer and a second dielectric layer on a semiconductor substrate; allowing the second dielectric layer and the first dielectric layer to undergo a first patterning process to define a first hole and a trench, a bottom surface of the first hole and a bottom surface of the trench being at a level higher than a level of a bottom surface of the first dielectric layer; forming a spacer layer covering a top surface of the second dielectric layer, an inner lateral surface and the bottom surface of the first hole, and covering an inner lateral surface and the bottom surface of the trench; forming on the spacer layer a sacrificial layer filling the first hole and the trench and covering the top surface of the second dielectric layer; allowing the sacrificial layer, the spacer layer, and the first dielectric layer to undergo a second patterning process to define a second hole, the second hole being inside the first hole; removing the sacrificial layer; forming on the spacer layer a conductive layer filling the first hole, the second hole, and the trench and covers the top surface of the second dielectric layer; and allowing the conductive layer to undergo a thinning process to expose the top surface of the second dielectric layer, forming a second semiconductor chip using the first method, joining the first semiconductor chip and the second semiconductor chip such that the conductive filing layer in each of the first holes are aligned and each of the second holes are aligned, heat treating the first semiconductor chip and the second semiconductor chip to bond the conductive filing layer in each of the first holes and each of the trenches . A wavelength of a light source used in the first patterning process may be greater than a wavelength of a light source used in the second patterning process.

According to some embodiments of the present inventive concepts, the method may further include forming a pad at an end of the trench, and wherein the conductive filing layer in each of the trenches of the first semiconductor pad and the second semiconductor pad overlap only at the pad.

### BRIEF DESCRIPTION OF DRAWINGS

FIG. 1 illustrates a cross-sectional view showing a semiconductor device according to some embodiments of the present inventive concepts.

FIG. 2 illustrates a plan view showing a semiconductor device according to some embodiments of the present inventive concepts.

FIGS. 3 to 5 illustrate cross-sectional views showing a semiconductor package according to some embodiments of the present inventive concepts.

FIG. 6 illustrates a plan view showing a semiconductor device according to some embodiments of the present inventive concepts.

FIGS. 7 to 10 illustrate cross-sectional views showing a semiconductor device according to some embodiments of the present inventive concepts.

FIGS. 11 to 18 illustrate cross-sectional views showing a method of fabricating a semiconductor device according to some embodiments of the present inventive concepts.

### DETAILED DESCRIPTION OF EMBODIMENTS

The following will now describe a semiconductor device according to the present inventive concepts with reference to accompanying drawings.

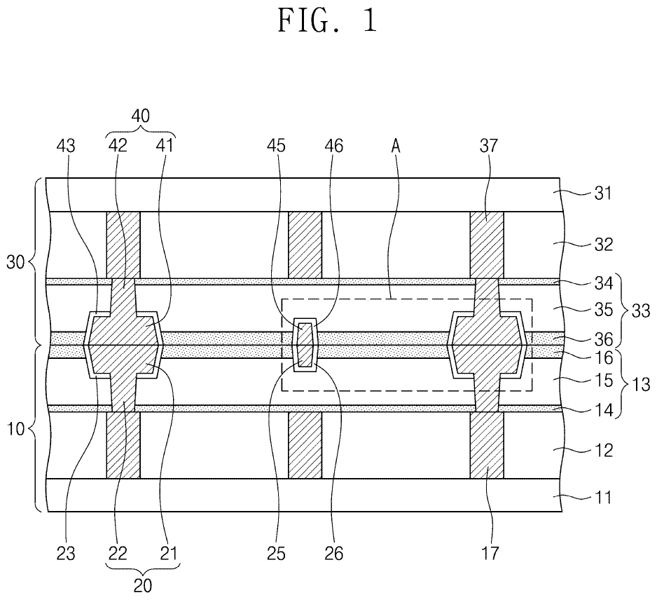

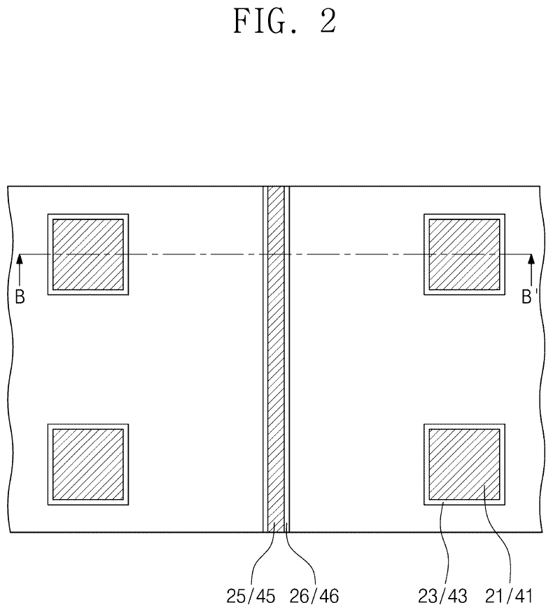

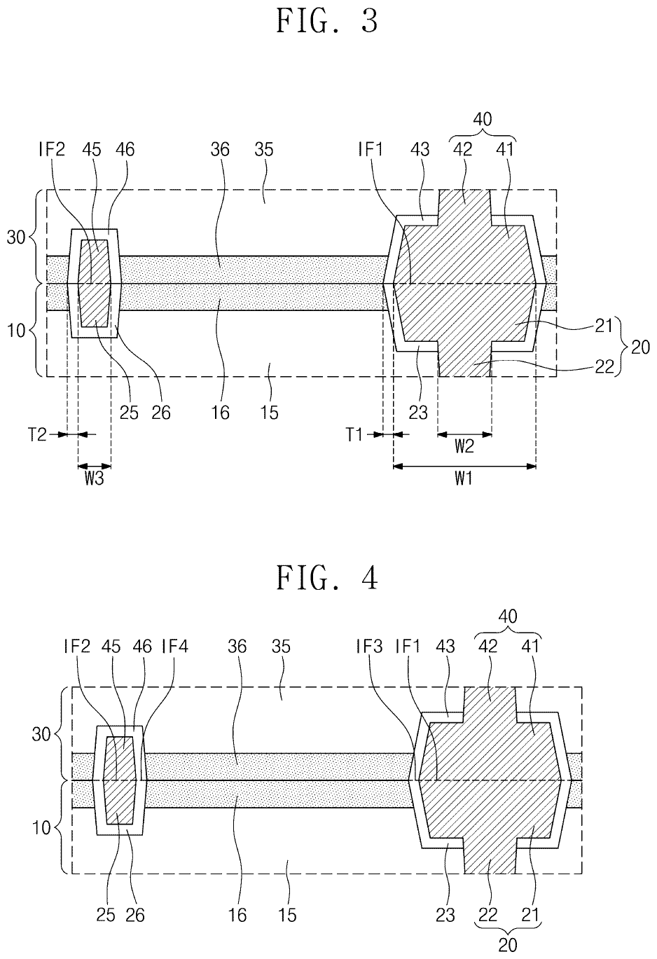

FIG. 1 illustrates a cross-sectional view showing a semiconductor device according to some embodiments of the present inventive concepts. FIG. 2 illustrates a cross-sectional view taken along line B-B′ of FIG. 1, showing a semiconductor device according to some embodiments of the present inventive concepts. FIGS. 3 and 4 illustrate enlarged cross-sectional view of section A of FIG. 1, showing a semiconductor device according to some embodiments of the present inventive concepts.

Referring to FIGS. 1 to 3, a semiconductor device may include a first semiconductor chip 10 and a second semiconductor chip 30 stacked on the first semiconductor chip 10.

The first semiconductor chip 10 may include a first substrate 11, a first circuit layer 12, a first dielectric layer 13, first pads 20, and first shield lines 25.

The first substrate 11 may be provided. The first substrate 11 may be a semiconductor substrate, such as a semiconductor wafer. The first substrate 11 may be a bulk silicon substrate, a silicon-on-insulator (SOI) substrate, a germanium substrate, a germanium-on-insulator (GOI) substrate, a silicon-germanium (SiGe) substrate, or an epitaxial film substrate obtained by performing selective epitaxial growth (SEG). The first substrate 11 may include, for example, at least one selected from silicon (Si), germanium (Ge), silicon germanium (SiGe), gallium arsenic (GaAs), indium gallium arsenic (InGaAs), aluminum gallium arsenic (AlGaAs), and a mixture thereof.

The first circuit layer 12 may be provided on the first substrate 11. The first circuit layer 12 may be disposed on a top surface of the first substrate 11. The first circuit layer 12 may include a first circuit pattern provided on the first substrate 11 and a first interlayer dielectric layer that covers the first circuit pattern. The first circuit pattern may be a memory circuit, a logic circuit, an optical device circuit, or a combination thereof, any of which circuits includes one or more transistors. Alternatively, the first circuit pattern may include a passive element, such as a resistor, an inductor, and/or a capacitor. The first dielectric layer 13 may include oxide, nitride, and/or oxynitride included in the first substrate 11. The first interlayer dielectric layer may include a dielectric material, such as silicon oxide (SiO), silicon nitride (SiN), silicon oxynitride (SiON), or silicon carbonitride (SiCN). For example, the first interlayer dielectric layer may include silicon oxide (SiO).

The first dielectric layer 13 may be disposed on the first circuit layer 12. The first dielectric layer 13 may cover a top surface of the first circuit layer 12. The first dielectric layer 13 may include a first sub-dielectric layer 14, a second sub-dielectric layer 15, and a third sub-dielectric layer 16 that are sequentially stacked on the first circuit layer 12.

The first sub-dielectric layer 14 may be disposed on the first circuit layer 12. The first sub-dielectric layer 14 may cover the top surface of the first circuit layer 12. The first sub-dielectric layer 14 may include a dielectric material different from that of the first interlayer dielectric layer of the first circuit layer 12. The first sub-dielectric layer 14 may include nitride. For example, the first sub-dielectric layer 14 may include silicon nitride (SiN). The first sub-dielectric layer 14 may be an etch barrier layer. The first sub-dielectric layer 14 may not be provided as desired.

The second sub-dielectric layer 15 may be disposed on the first sub-dielectric layer 14. The second sub-dielectric layer 15 may cover a top surface of the first sub-dielectric layer 14. The second sub-dielectric layer 15 may include a dielectric material different from that of the first sub-dielectric layer 14. The second sub-dielectric layer 15 may include oxide. For example, the second sub-dielectric layer 15 may include silicon oxide (SiO). The second sub-dielectric layer 15 may be a dielectric layer for being provided with the first pads 20 and the first shield lines 25 which will be discussed below.

The third sub-dielectric layer 16 may be disposed on the second sub-dielectric layer 15. The third sub-dielectric layer 16 may cover a top surface of the second sub-dielectric layer 15. The third sub-dielectric layer 16 may include a dielectric material different from that of the second sub-dielectric layer 15. The third sub-dielectric layer 16 may include nitride. For example, the third sub-dielectric layer 16 may include silicon nitride (SiN). The third sub-dielectric layer 16 may be an etch barrier layer. The third sub-dielectric layer 16 may not be provided as desired.

The first pads 20 and the first shield lines 25 may be provided in the first dielectric layer 13.

The first pads 20 may vertically penetrate the first dielectric layer 13 to come into coupling with the first circuit layer 12. The first pads 20 may vertically penetrate the first sub-dielectric layer 14, the second sub-dielectric layer 15, and the third sub-dielectric layer 16. For example, when the first pads 20 are signal pads, the first pads 20 may be electrically connected to the first circuit layer 12, for example, to the first circuit pattern formed on the first substrate 11.

As illustrated in FIG. 1, a first connection line 17 may be provided in the first circuit layer 12. The first connection line 17 may be a through via that vertically penetrates the first interlayer dielectric layer provided in the first circuit layer 12. The first connection line 17 may vertically extend in the first circuit layer 12 to come into coupling with the first pads 20. The first connection line 17 may electrically connect the first circuit pattern to the first pads 20. When the first pads 20 are dummy pads, the first connection line 17 may not be coupled to the first pads 20. Although not shown, various wiring conductive patterns may be provided between the first circuit pattern and the first connection line 17.

In some example embodiments, differently from that shown in FIG. 1, the first connection line 17 may be an under-pad pattern or a redistribution pattern provided in a dielectric pattern of the first circuit layer 12. In this case, various wiring conductive patterns may be provided between the first circuit pattern and the first connection line 17. The present inventive concepts, however, are not limited thereto. For example, the first circuit layer 12 may be provided in various forms as desired, and electrical connections between the first pads 20 and the first circuit layer 12 may be achieved through various configurations as desired.

When viewed in plan, the first pads 20 may be arranged in a grid shape as illustrated in FIG. 2. The present inventive concepts, however, are not limited thereto, and the first pads 20 may be arranged in various forms as desired.

Each of the first pads 20 may include a first pad part 21 and a first via part 22. The following description will focus on a configuration of the first pad part 21 and the first via part 22 of one first pad 20.

The first pad part 21 may be a pad portion through which the first semiconductor chip 10 is connected to the second semiconductor chip 30. The first pad part 21 may be exposed on a top surface of the third sub-dielectric layer 16. A top surface of the first pad part 21 may be flat or substantially flat coplanar with that of the third sub-dielectric layer 16. The first pad part 21 may vertically penetrate the third sub-dielectric layer 16. The first pad part 21 may vertically penetrate at least a portion of the second sub-dielectric layer 15. A bottom surface of the first pad part 21 may be positioned between top and bottom surfaces of the second sub-dielectric layer 15. However, differently from that shown in FIGS. 1 and 3, the bottom surface of the first pad part 21 may be positioned between top and bottom surfaces of the third sub-dielectric layer 16.

The following description will focus on some embodiments of FIG. 1. The first pad part 21 may have a tapered shape when viewed in cross-section. A first width W1 of the first pad part 21 may decrease in a direction toward the first substrate 11 from the top surface of the third sub-dielectric layer 16. According to some embodiments, the first width W1 of the first pad part 21 may be constant irrespective of distance from the top surface of the third sub-dielectric layer 16. The first pad part 21 may have a tetragonal planar shape. However, differently from that shown in FIG. 2, the first pad part 21 may have a circular shape, a linear shape, a polygonal shape, or any other suitable shape when viewed in plan.

The following description will focus on some embodiments of FIG. 2. The first pad part 21 may include a metallic material. For example, the first pad part 21 may include copper (Cu).

The first via part 22 may be disposed beneath the first pad part 21. The first via part 22 may be a vertical connector for connecting the first pad part 21 to the first circuit layer 12 or the first pad part 21 to the first substrate 11. The first via part 22 may extend from the bottom surface of the first pad part 21. The first via part 22 may be in contact with the bottom surface of the first pad part 21. For example, the first via part 22 may be connected to the first pad part 21.

The first via part 22 may vertically penetrate at least a portion of the second sub-dielectric layer 15. The first via part 22 may vertically penetrate the first sub-dielectric layer 14. The first via part 22 may be exposed on a bottom surface of the first sub-dielectric layer 14. The first via part 22 may be electrically connected to the first circuit layer 12, for example, to the first circuit pattern formed on the first substrate 11. Alternatively, as desired, the first via part 22 may be directly connected to the first substrate 11.

A bottom surface of the first via part 22 may be flat or substantially flat coplanar with that of the first sub-dielectric layer 14. The first via part 22 may have a pillar shape. The first via part 22 may have a tapered shape when viewed in cross-section. A second width W2 of the first via part 22 may decrease in a direction toward the first substrate 11 from the bottom surface of the first pad part 21. According to some embodiments, the second width W2 of the first via part 22 may be constant irrespective of distance from the bottom surface of the first pad part 21. A width of the first via part 22 may be less than that of the first pad part 21. For example, on a contact surface between the first via part 22 and the first pad part 21, a width at the bottom surface of the first pad part 21 may be greater than a width at a top surface of the first via part 22.

The first via part 22 may have a circular shape, a tetragonal shape, a polygonal shape, or any other suitable shape when viewed in plan. The first via part 22 may include a metallic material. For example, the first via part 22 may include copper (Cu).

For convenience of description in this disclosure, the first pad part 21 and the first via part 22 are named differently from each other, but the first pad part 21 and the first via part 22 are not separate components. The first pad part 21 and the first via part 22 may be portions of one first pad 20, and may be provided as a single unitary piece formed of the same material.

Although not shown, each of the first pads 20 may further include a first seed layer. The first seed layers may surround the first pads 20. For example, in one first pad 20, the first seed layer may cover a lateral surface of the first pad part 21, a bottom surface of the first pad part 21 not covered with the first via part 22, and a lateral surface of the first via part 22. The first seed layers may include a metallic material, such as gold (Au).

The first pads 20 may further include corresponding first spacer patterns 23. In one first pad 20, the first spacer pattern 23 may be interposed between the first pad part 21 and the first dielectric layer 13. For example, the first spacer pattern 23 may cover the lateral surface of the first pad part 21 and the bottom surface of the first pad part 21 not covered with the first via part 22. For example, the first spacer pattern 23 may cover the lateral and bottom surfaces of the first pad part 21, and on the bottom surface of the first pad part 21, the first via part 22 may vertically penetrate the first spacer pattern 23 to extend into the first dielectric layer 13. The first spacer pattern 23 may separate the first pad part 21 from the first dielectric layer 13.

The first spacer pattern 23 may be in partial contact with an upper lateral surface of the first via part 22. An uppermost end of the first spacer pattern 23 may be exposed on the top surface of the third sub-dielectric layer 16. The uppermost end of the first spacer pattern 23 may be located at a vertical level the same as that of the top surface of the third sub-dielectric layer 16. For example, a top surface of the first spacer pattern 23 may be flat or substantially flat coplanar with that of the third sub-dielectric layer 16.

A first thickness T1 of the first spacer pattern 23 may range from about or exactly 10 nanometers to about or exactly 100 nanometers. In this description, a thickness of the first spacer pattern 23 may refer to a width of a gap between the first pad part 21 and the first dielectric layer 13. The first spacer pattern 23 may include a dielectric material different from that of the third sub-dielectric layer 16. The first spacer pattern 23 may include oxide. For example, the first spacer pattern 23 may include silicon oxide (SiO) or tetraethylorthosilicate (TEOS).

The first shield lines 25 may be provided in the first dielectric layer 13. The following description will focus on one first shield line 25. The first shield line 25 may be exposed on the top surface of the third sub-dielectric layer 16. A top surface of the first shield line 25 may be flat or substantially flat coplanar with that of the third sub-dielectric layer 16.

The first shield line 25 may vertically penetrate the third sub-dielectric layer 16. The first shield line 25 may vertically penetrate at least a portion of the second sub-dielectric layer 15. A bottom surface of the first shield line 25 may be positioned between the top and bottom surfaces of the second sub-dielectric layer 15. However, differently from that shown in FIGS. 1 and 3, the bottom surface of the first shield line 25 may be positioned between the top and bottom surfaces of the third sub-dielectric layer 16.

The following description will focus on some embodiments of FIG. 1. The bottom surface of the first shield line 25 may be located at a vertical level higher than the bottom surface of the first pad part 21. For example, the bottom surface of the first pad part 21 may be closer than the bottom surface of the first shield line 25 to the first substrate 11.

The first shield line 25 may have a tapered shape when viewed in cross-section. A third width W3 of the first shield line 25 may decrease in a direction toward the first substrate 11 from the top surface of the third sub-dielectric layer 16. According to some embodiments, the third width W3 of the first shield line 25 may be constant irrespective of distance from the top surface of the third sub-dielectric layer 16. The third width W3 of the first shield line 25 may range from about or exactly 100 nanometers to about or exactly 140 nanometers. The third width W3 of the first shield line 25 may refer to a width of the first shield line 25 measured on the top surface of the first shield line 25.

The first shield line 25 may have a linear shape when viewed in plan. For example, the first shield line 25 may be disposed horizontally spaced apart from the first pads 20. When viewed in plan, the first shield line 25 may run across between the first pads 20 or may be disposed on one side of the first pads 20.

The first shield line 25 may be provided to prevent or reduce a short-circuit or electrical shield between the first pads 20. Although not shown, the first shield line 25 may be electrically connected to a ground circuit formed on the first substrate 11. The first shield line 25 may include a material the same as that of the first pads 20, for example, that of the first pad part 21 and the first via part 22. The first shield line 25 may include a metallic material. For example, the first shield line 25 may include copper (Cu).

Although not shown, each of the first shield lines 25 may further include a second seed layer. The second seed layers may surround the first shield lines 25. For example, in one first shield line 25, the second seed layer may cover lateral and bottom surfaces of the first shield line 25. The second seed layers may include a metallic material, such as gold (Au).

Second spacer patterns 26 may be interposed between the first shield lines 25 and the first dielectric layer 13. In one first shield line 25, the second spacer pattern 26 may be interposed between the first shield line 25 and the first dielectric layer 13. For example, the second spacer pattern 26 may cover the lateral and bottom surfaces of the first shield line 25. The second spacer pattern 26 may separate the first shield line 25 from the first dielectric layer 13.

An uppermost end of the second spacer pattern 26 may be exposed on the top surface of the third sub-dielectric layer 16. The uppermost end of the second spacer pattern 26 may be located at a vertical level the same as that of the top surface of the third sub-dielectric layer 16. For example, a top surface of the second spacer pattern 26 may be flat or substantially flat coplanar with that of the third sub-dielectric layer 16. A second thickness T2 of the second spacer pattern 26 may range from about or exactly 10 nanometers to about or exactly 100 nanometers. In this description, a thickness of the second spacer pattern 26 may refer to a width of a gap between the first shield line 25 and the first dielectric layer 13.

The second spacer pattern 26 may include a material the same as that of the first spacer pattern 23. The second spacer pattern 26 may include a dielectric material different from that of the third sub-dielectric layer 16. The second spacer pattern 26 may include oxide. For example, the second spacer pattern 26 may include silicon oxide (SiO) or tetraethylorthosilicate (TEOS).

The second semiconductor chip 30 may be disposed on the first semiconductor chip 10.

The second semiconductor chip 30 may include a second substrate 31, a second circuit layer 32, a second dielectric layer 33, second pads 40, and second shield lines 45.

The second substrate 31 may be provided. The second substrate 31 may be a semiconductor substrate, such as a semiconductor wafer. The second substrate 31 may be a bulk silicon substrate, a silicon-on-insulator (SOI) substrate, a germanium substrate, a germanium-on-insulator (GOI) substrate, a silicon-germanium (SiGe) substrate, or an epitaxial film substrate obtained by performing a selective epitaxial growth (SEG). The second substrate 31 may include, for example, at least one selected from silicon (Si), germanium (Ge), silicon germanium (SiGe), gallium arsenic (GaAs), indium gallium arsenic (InGaAs), aluminum gallium arsenic (AlGaAs), and a mixture thereof.

The second circuit layer 32 may be provided beneath the second substrate 31. The second circuit layer 32 may be disposed on a bottom surface of the second substrate 31. The second circuit layer 32 may include a second circuit pattern provided on the second substrate 31 and a second interlayer dielectric layer that covers the second circuit pattern. The second circuit pattern may be a memory circuit, a logic circuit, an optical device circuit, or a combination thereof, any of which circuits includes one or more transistors. Alternatively, the second circuit pattern may include a passive element, such as a resistor, an inductor, and/or a capacitor. The second dielectric layer 33 may include oxide, nitride, and/or oxynitride included in the second substrate 31. The second interlayer dielectric layer may include a dielectric material, such as silicon oxide (SiO), silicon nitride (SiN), silicon oxynitride (SiON), or silicon carbonitride (SiCN). For example, the second interlayer dielectric layer may include silicon oxide (SiO).

According to some embodiments, differently from that shown in FIG. 1, the second circuit layer 32 may be disposed on a top surface of the second substrate 31.

The second dielectric layer 33 may be disposed on the second circuit layer 32. The second dielectric layer 33 may cover a bottom surface of the second circuit layer 32. The second dielectric layer 33 may include a fourth sub-dielectric layer 34, a fifth sub-dielectric layer 35, and a sixth sub-dielectric layer 36 that are sequentially stacked on the second circuit layer 32.

The fourth sub-dielectric layer 34 may be disposed on the second circuit layer 32. The fourth sub-dielectric layer 34 may cover the bottom surface of the second circuit layer 32. The fourth sub-dielectric layer 34 may include a dielectric material different from that of the second interlayer dielectric layer of the second circuit layer 32. The fourth sub-dielectric layer 34 may include nitride. For example, the fourth sub-dielectric layer 34 may include silicon nitride (SiN). The fourth sub-dielectric layer 34 may be an etch barrier layer. The fourth sub-dielectric layer 34 may not be provided as desired.

The fifth sub-dielectric layer 35 may be disposed on the fourth sub-dielectric layer 34. The fifth sub-dielectric layer 35 may cover a bottom surface of the fourth sub-dielectric layer 34. The fifth sub-dielectric layer 35 may include a dielectric material different from that of the fourth sub-dielectric layer 34. The fifth sub-dielectric layer 35 may include oxide. For example, the fifth sub-dielectric layer 35 may include silicon oxide (SiO). The fifth sub-dielectric layer 35 may be a dielectric layer for being provided with the second pads 40 and the second shield lines 45 which will be discussed below.

The sixth sub-dielectric layer 36 may be disposed on the fifth sub-dielectric layer 35. The sixth sub-dielectric layer 36 may cover a bottom surface of the fifth sub-dielectric layer 35. The sixth sub-dielectric layer 36 may include a dielectric material different from that of the fifth sub-dielectric layer 35. The sixth sub-dielectric layer 36 may include nitride. For example, the sixth sub-dielectric layer 36 may include silicon nitride (SiN). The sixth sub-dielectric layer 36 may be an etch barrier layer. The sixth sub-dielectric layer 36 may not be provided as desired.

The second pads 40 and the second shield lines 45 may be provided in the second dielectric layer 33.

The second pads 40 may vertically penetrate the second dielectric layer 33 to come into coupling with the second circuit layer 32. The second pads 40 may vertically penetrate the fourth sub-dielectric layer 34, the fifth sub-dielectric layer 35, and the sixth sub-dielectric layer 36. For example, when the second pads 40 are signal pads, the second pads 40 may be electrically connected to the second circuit layer 32, for example, to the second circuit pattern formed on the second substrate 31.

As illustrated in FIG. 1, a second connection line 37 may be provided in the second circuit layer 32. The second connection line 37 may be a through via that vertically penetrates the second interlayer dielectric layer provided in the second circuit layer 32. The second connection line 37 may vertically extend in the second circuit layer 32 to come into coupling with the second pads 40. The second connection line 37 may electrically connect the second circuit pattern to the second pads 40. When the second pads 40 are dummy pads, the second connection line 37 may not be coupled to the second pads 40. Although not shown, various wiring conductive patterns may be provided between the second circuit pattern and the second connection line 37.

In some embodiments, differently from that shown in FIG. 1, the second connection line 37 may be an under-pad pattern or a redistribution pattern provided in a dielectric pattern in the second circuit layer 32. In this case, various wiring conductive patterns may be provided between the second circuit pattern and the second connection line 37. The present inventive concepts, however, are not limited thereto. For example, the second circuit layer 32 may be provided in various forms as desired, and electrical connections between the second pads 40 and the second circuit layer 32 may be achieved through various configurations as desired.

When viewed in plan, the second pads 40 may be arranged in a grid shape. The present inventive concepts, however, are not limited thereto, and the second pads 40 may be arranged in various forms as desired.

Each of the second pads 40 may include a second pad part 41 and a second via part 42. The following description will focus on a configuration of the second pad part 41 and the second via part 42 of one second pad 40.

The second pad part 41 may be a pad portion through which the second semiconductor chip 30 is connected to the first semiconductor chip 10. The second pad part 41 may be exposed on a bottom surface of the sixth sub-dielectric layer 36. A bottom surface of the second pad part 41 may be flat or substantially flat coplanar with that of the sixth sub-dielectric layer 36. The second pad part 41 may vertically penetrate the sixth sub-dielectric layer 36. The second pad part 41 may vertically penetrate at least a portion of the fifth sub-dielectric layer 35.

A top surface of the second pad part 41 may be positioned between top and bottom surfaces of the fifth sub-dielectric layer 35. However, differently from that shown in FIGS. 1 and 3, the top surface of the second pad part 41 may be positioned between top and bottom surfaces of the sixth sub-dielectric layer 36. The following description will focus on some embodiments of FIG. 1.

The second pad part 41 may have a tapered shape when viewed in cross-section. A width of the second pad part 41 may decrease in a direction toward the second substrate 31 from the bottom surface of the sixth sub-dielectric layer 36. According to some embodiments, the width of the second pad part 41 may be constant irrespective of distance from the bottom surface of the sixth sub-dielectric layer 36.

The second pad part 41 may have a tetragonal planar shape. However, differently from that shown in FIG. 2, the second pad part 41 may have a circular shape, a linear shape, a polygonal shape, or any other suitable shape when viewed in plan. The following description will focus on some embodiments of FIG. 2. The second pad part 41 may include a metallic material. For example, the second pad part 41 may include copper (Cu).

The second via part 42 may be disposed on the second pad part 41. The second via part 42 may be a vertical connector for connecting the second pad part 41 to the second circuit layer 32 or the second substrate 31. The second via part 42 may extend from the top surface of the second pad part 41. The second via part 42 may be in contact with the top surface of the second pad part 41. For example, the second via part 42 may be connected to the second pad part 41.

The second via part 42 may vertically penetrate at least a portion of the fifth sub-dielectric layer 35. The second via part 42 may vertically penetrate the fourth sub-dielectric layer 34. The second via part 42 may be exposed on a top surface of the fourth sub-dielectric layer 34. The second via part 42 may be electrically connected to the second circuit layer 32, for example, to the second circuit pattern formed on the second substrate 31. Alternatively, as desired, the second via part 42 may be directly connected to the second substrate 31.

A top surface of the second via part 42 may be flat or substantially flat coplanar with that of the fourth sub-dielectric layer 34. The second via part 42 may have a pillar shape. The second via part 42 may have a tapered shape when viewed in cross-section. A width of the second via part 42 may decrease in a direction toward the second substrate 31 from the top surface of the second pad part 41. According to some embodiments, the width of the second via part 42 may be constant irrespective of distance from the top surface of the second pad part 41. The width of the second via part 42 may be less than that of the second pad part 41. For example, on a contact surface between the second via part 42 and the second pad part 41, a width at the top surface of the second pad part 41 may be greater than a width at a bottom surface of the second via part 42.

The second via part 42 may have a circular shape, a tetragonal shape, a polygonal shape, or any other suitable shape when viewed in plan. The second via part 42 may include a metallic material. For example, the second via part 42 may include copper (Cu).

For convenience of description in this disclosure, the second pad part 41 and the second via part 42 are named differently from each other, but the second pad part 41 and the second via part 42 are not separate components. The second pad part 41 and the second via part 42 may be portions of one second pad 40, and may be provided as a single unitary piece formed of the same material.

Although not shown, each of the second pads 40 may further include a third seed layer. The third seed layers may surround the second pads 40. For example, in one second pad 40, the third seed layer may cover a lateral surface of the second pad part 41, a top surface of the second pad part 41 not covered with the second via part 42, and a lateral surface of the second via part 42. The third seed layers may include a metallic material, such as gold (Au).

Each of the second pads 40 may further include a third spacer pattern 43. In one second pad 40, the third spacer pattern 43 may be interposed between the second pad part 41 and the second dielectric layer 33. The third spacer pattern 43 may cover the lateral surface of the second pad part 41 and the top surface of the second pad part 41 not covered with the second via part 42. For example, the third spacer pattern 43 may cover the lateral and bottom surfaces of the second pad part 41, and on the top surface of the second pad part 41, the second via part 42 may vertically penetrate the third spacer pattern 43 to extend into the second dielectric layer 33.

The third spacer pattern 43 may separate the second pad part 41 from the second dielectric layer 33. The third spacer pattern 43 may be in partial contact with a lower lateral surface of the second via part 42. A lowermost end of the third spacer pattern 43 may be exposed on the bottom surface of the sixth sub-dielectric layer 36. The lowermost end of the third spacer pattern 43 may be located at a vertical level the same as that of the bottom surface of the sixth sub-dielectric layer 36. For example, a bottom surface of the third spacer pattern 43 may be flat or substantially flat coplanar with that of the sixth sub-dielectric layer 36. A thickness of the third spacer pattern 43 may range from about or exactly 10 nanometers to about or exactly 100 nanometers. In this description, the thickness of the third spacer pattern 43 may refer to a width of a gap between the second pad part 41 and the second dielectric layer 33.

The third spacer pattern 43 may include a dielectric material different from that of the sixth sub-dielectric layer 36. The third spacer pattern 43 may include oxide. For example, the third spacer pattern 43 may include silicon oxide (SiO) or tetraethylorthosilicate (TEOS).

The second shield lines 45 may be provided in the second dielectric layer 33. The following description will focus on one second shield line 45. The second shield line 45 may be exposed on the bottom surface of the sixth sub-dielectric layer 36. A bottom surface of the second shield line 45 may be flat or substantially flat coplanar with that of the sixth sub-dielectric layer 36. The second shield line 45 may vertically penetrate the sixth sub-dielectric layer 36. The second shield line 45 may vertically penetrate at least a portion of the fifth sub-dielectric layer 35.

A top surface of the second shield line 45 may be positioned between the top and bottom surfaces of the fifth sub-dielectric layer 35. However, differently from that shown in FIGS. 1 and 3, the top surface of the second shield line 45 may be positioned between the top and bottom surfaces of the sixth sub-dielectric layer 36. The following description will focus on some embodiments of FIG. 1.

The top surface of the second shield line 45 may be located at a vertical level lower than that of the bottom surface of the second pad part 41. For example, the top surface of the second pad part 41 may be closer than the top surface of the second shield line 45 to the second substrate 31. The second shield line 45 may have a tapered shape when viewed in cross-section. A width of the second shield line 45 may decrease in a direction toward the second substrate 31 from the bottom surface of the sixth sub-dielectric layer 36. According to some embodiments, the width of the second shield line 45 may be constant irrespective of distance from the bottom surface of the sixth sub-dielectric layer 36.

The width of the second shield line 45 may range from about or exactly 100 nanometers to about or exactly 140 nanometers. In this description, the width of the second shield line 45 may refer to a width of the second shield line 45 measured on the bottom surface of the second shield line 45. The second shield line 45 may have a linear shape when viewed in plan. For example, the second shield line 45 may be disposed horizontally spaced apart from the second pads 40. When viewed in plan, the second shield line 45 may run across between the second pads 40 or may be disposed on one side of the second pads 40.

The second shield line 45 may be provided to prevent or reduce a short-circuit or electrical shield between the second pads 40. Although not shown, the second shield line 45 may be electrically connected to a ground circuit formed on the second substrate 31. Alternatively, the second shield line 45 may be connected to the first shield line 25, and may be electrically connected through the first shield line 25 to a ground circuit formed on the first substrate 11.

The second shield line 45 may include a material the same as that of the second pads 40, for example, that of the second pad part 41 and the second via part 42. The second shield line 45 may include a metallic material. For example, the second shield line 45 may include copper (Cu).

Although not shown, each of the second shield lines 45 may further include a fourth seed layer. The fourth seed layers may surround the second shield lines 45. For example, in one second shield line 45, the fourth seed layer may cover lateral and top surfaces of the second shield line 45. The fourth seed layers may include a metallic material, such as gold (Au).

Fourth spacer patterns 46 may be interposed between the second shield lines 45 and the second dielectric layer 33. In one second shield line 45, the fourth spacer pattern 46 may be interposed between the second shield line 45 and the second dielectric layer 33. For example, the fourth spacer pattern 46 may cover the lateral and top surfaces of the second shield line 45. The fourth spacer pattern 46 may separate the second shield line 45 from the second dielectric layer 33.

A lowermost end of the fourth spacer pattern 46 may be exposed on the bottom surface of the sixth sub-dielectric layer 36. The lowermost end of the fourth spacer pattern 46 may be located at a vertical level the same as that of the bottom surface of the sixth sub-dielectric layer 36. For example, a top surface of the fourth spacer pattern 46 may be flat or substantially flat coplanar with the bottom surface of the sixth sub-dielectric layer 36. A thickness of the fourth spacer pattern 46 may range from about or exactly 10 nanometers to about or exactly 100 nanometers. In this description, the thickness of the fourth spacer pattern 46 may refer to a width of a gap between the second shield line 45 and the second dielectric layer 33.

The fourth spacer pattern 46 may include a material the same as that of the third spacer pattern 43. The fourth spacer pattern 46 may include a dielectric material different from that of the sixth sub-dielectric layer 36. The fourth spacer pattern 46 may include oxide. For example, the fourth spacer pattern 46 may include silicon oxide (SiO) or tetraethylorthosilicate (TEOS).

The second semiconductor chip 30 may be connected to the first semiconductor chip 10. For example, the second semiconductor chip 30 and the first semiconductor chip 10 may be bonded to each other. On an interface between the second semiconductor chip 30 and the first semiconductor chip 10, the third sub-dielectric layer 16 of the first semiconductor chip 10 may be in contact with the sixth sub-dielectric layer 36 of the second semiconductor chip 30. The first pads 20 of the first semiconductor chip 10 may be vertically aligned with the second pads 40 of the second semiconductor chip 30. The first shield lines 25 may be vertically aligned with the second shield lines 45.

On the interface between the second semiconductor chip 30 and the first semiconductor chip 10, the first pads 20 may be bonded to the second pads 40, and the first shield lines 25 may be bonded to the second shield lines 45. In this case, the first pads 20 and the second pads 40 may constitute an intermetallic hybrid bonding. The first shield lines 25 and the second shield lines 45 may constitute an intermetallic hybrid bonding. In this description, the term “hybrid bonding” may denote a bonding in which two components of the same kind are merged at an interface therebetween.

The bonded first and second pads 20 and 40 may have a continuous configuration, and an invisible interface IF1 may be present between the first pad 20 and the second pad 40. For example, the first and second pads 20 and 40 may be formed of the same material, and may thus have no interface therebetween. In this case, the first and second pads 20 and 40 may be provided as a single component. For example, the first pad 20 and the second pad 40 may be bonded into a single unitary piece.

The bonded first and second shield lines 25 and 45 may have a continuous configuration, and an invisible interface IF2 may be present between the first shield line 25 and the second shield line 45. For example, the first and second shield lines 25 and 45 may be formed of the same material, and may thus have no interface therebetween. In this case, the first and second shield lines 25 and 45 may be provided as a single component. For example, the first and second shield lines 25 and 45 may be bonded into a single unitary piece.

On the interface between the second semiconductor chip 30 and the first semiconductor chip 10, the first spacer pattern 23 of the first semiconductor chip 10 may be bonded to the third spacer pattern 43 of the second semiconductor chip 30. On the interface between the second semiconductor chip 30 and the first semiconductor chip 10, the second spacer pattern 26 of the first semiconductor chip 10 may be bonded to the fourth spacer pattern 46 of the second semiconductor chip 30. FIG. 3 depicts that an invisible interface is present between the first spacer pattern 23 and the third spacer pattern 43 and between the second spacer pattern 26 and the fourth spacer pattern 46, but the present inventive concepts are not limited thereto.

According to some embodiments, as illustrated in FIG. 4, the first spacer pattern 23 and the third spacer pattern 43 may be bonded to each other, and the second spacer pattern 26 and the fourth spacer pattern 46 may be bonded to each other. For example, the first spacer pattern 23 and the third spacer pattern 43 may constitute an oxide-to-oxide hybrid bonding, and the second spacer pattern 26 and the fourth spacer pattern 46 may constitute an oxide-to-oxide hybrid bonding.

The bonded first and third spacer patterns 23 and 43 may have a continuous configuration, and an invisible interface IF3 may be present between the first spacer pattern 23 and the third spacer pattern 43. The bonded second and fourth spacer patterns 26 and 46 may have a continuous configuration, and an invisible interface IF4 may be present between the second spacer pattern 26 and the fourth spacer pattern 46.

According to some embodiments of the present inventive concepts, the first pads 20 and the first shield lines 25 may be provided in holes or trenches formed in the first dielectric layer 13 of the first semiconductor chip 10. In this case, the first spacer pattern 23 or the second spacer pattern 26 may be provided in the holes or the trenches, and thus the first pads 20 and the first shield lines 25 may be provided to have their small widths.

The first pads 20 and the first shield lines 25 may have their widths less than those of the holes or the trenches. For example, the first shield lines 25 having linear shapes may be provided to have their fine line-widths. In addition, there may be provided the second pads 40 and the second shield lines 45 having small widths. For example, the second shield lines 45 having linear shapes may be provided to have their fine line-widths. As a result, it may be possible to provide a semiconductor device with improved integration.

In some embodiments that follow, a detailed description of technical features repetitive to those discussed with reference to FIGS. 1 to 4 will be omitted for convenience of description, and a difference thereof will be discussed in detail. The same reference numerals may be allocated to the same components as those of the semiconductor device discussed above according to some embodiments of the present inventive concepts.

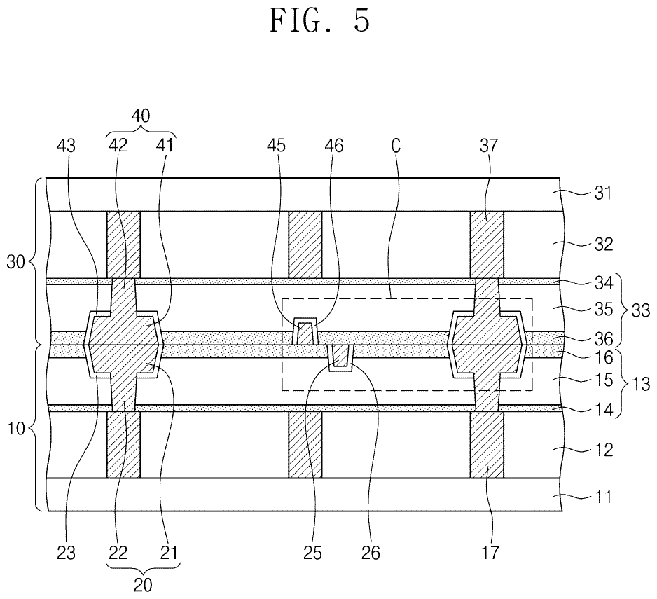

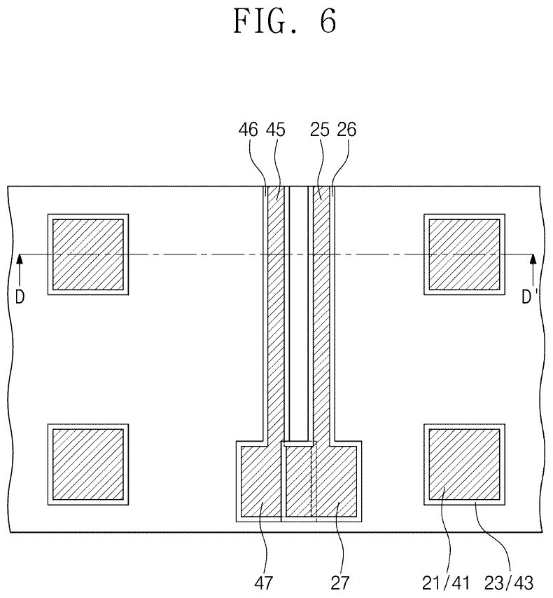

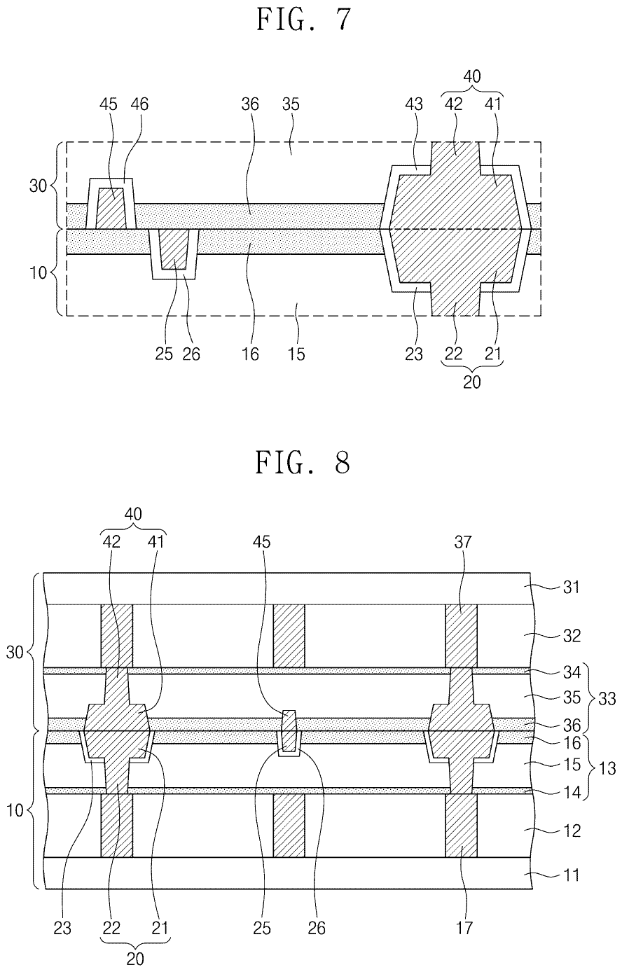

FIG. 5 illustrates a cross-sectional view showing a semiconductor device according to some embodiments of the present inventive concepts. FIG. 6 illustrates a cross-sectional view taken along line D-D′ of FIG. 5, showing a semiconductor device according to some embodiments of the present inventive concepts. FIG. 7 illustrates an enlarged cross-sectional view of section C depicted in FIG. 5, showing a semiconductor device according to some embodiments of the present inventive concepts.

Referring to FIGS. 5 to 7, the first semiconductor chip 10 may further include a third pad part 27. The third pad part 27 may be a pad portion for connecting the first shield lines 25 of the first semiconductor chip 10 to the second shield lines 45 of the second semiconductor chip 30. The third pad part 27 may be exposed on the top surface of the third sub-dielectric layer 16. A top surface of the third pad part 27 may be flat or substantially flat coplanar with that of the third sub-dielectric layer 16. A bottom surface of the third pad part 27 may be positioned between the top and bottom surfaces of the second sub-dielectric layer 15.

The third pad part 27 may have a tetragonal shape, a circular shape, a polygonal shape, or any other suitable shape when viewed in plan. The first shield lines 25 may be connected to the third pad part 27. For example, as illustrated in FIG. 6, the first shield lines 25 may extend in one direction from the third pad part 27. The first shield lines 25 and the third pad part 27 may constitute a single unitary piece. The first shield lines 25 and the third pad part 27 may include the same material. The third pad part 27 may include a metallic material. For example, the third pad part 27 may include copper (Cu).

The second spacer patterns 26 may surround the first shield lines 25 and the third pad part 27. For example, the second spacer patterns 26 may be interposed between the first shield lines 25, the third pad part 27, and the first dielectric layer 13.

The second semiconductor chip 30 may further include a fourth pad part 47. The fourth pad part 47 may be a pad portion for connecting the second shield lines 45 of the second semiconductor chip 30 to the first shield lines 25 of the first semiconductor chip 10. The fourth pad part 47 may be exposed on the bottom surface of the sixth sub-dielectric layer 36. A bottom surface of the fourth pad part 47 may be flat or substantially flat coplanar with that of the sixth sub-dielectric layer 36. A top surface of the fourth pad part 47 may be positioned between the top and bottom surfaces of the fifth sub-dielectric layer 35.

The fourth pad part 47 may have a tetragonal shape, a circular shape, a polygonal shape, or any other suitable shape when viewed in plan. The second shield lines 45 may be connected to the fourth pad part 47. For example, as illustrated in FIG. 6, the second shield lines 45 may extend in one direction from the fourth pad part 47. The second shield lines 45 and the fourth pad part 47 may constitute a single unitary piece. The second shield lines 45 and the fourth pad part 47 may include the same material. The fourth pad part 47 may include a metallic material. For example, the fourth pad part 47 may include copper (Cu).

The fourth spacer patterns 46 may surround the second shield lines 45 and the fourth pad part 47. For example, the fourth spacer patterns 46 may be interposed between the second shield lines 45, the fourth pad part 47, and the second dielectric layer 33.

The second semiconductor chip 30 may be connected to the first semiconductor chip 10. For example, the second semiconductor chip 30 and the first semiconductor chip 10 may be bonded to each other.

The first pads 20 of the first semiconductor chip 10 may be vertically aligned with the second pads 40 of the second semiconductor chip 30. The first shield lines 25 may be horizontally shifted from the second shield lines 45. For example, when viewed in plan as illustrated in FIG. 6, the first shield lines 25 may be horizontally spaced apart from the second shield lines 45. The third pad part 27 and the fourth pad part 47 may overlap each other. In this case, the third pad part 27 may overlap at least a portion of the fourth pad part 47.

On the interface between the second semiconductor chip 30 and the first semiconductor chip 10, the first shield lines 25 and the second semiconductor chip 30 may be in contact with a bottom surface of the second dielectric layer 33 (or the bottom surface of the sixth sub-dielectric layer 36), and the second shield lines 45 may be in contact with a top surface of the first dielectric layer 13 (or the top surface of the third sub-dielectric layer 16).

On the interface between the second semiconductor chip 30 and the first semiconductor chip 10, the third pad part 27 and the fourth pad part 47 may be in contact with each other. On the interface between the second semiconductor chip 30 and the first semiconductor chip 10, the third pad part 27 and the fourth pad part 47 may be bonded to each other. In this configuration, the third pad part 27 and the fourth pad part 47 may constitute an intermetallic hybrid bonding. The bonded third and fourth pad parts 27 and 47 may have a continuous configuration, and an invisible interface may be present between the third pad part 27 and the fourth pad part 47.

According to some embodiments of the present inventive concepts, the first shield lines 25 and the second shield lines 45 may be provided to have their fine line-widths. The first shield lines 25 and the second shield lines 45 may be horizontally shifted from each other in accordance with a process error of fabrication process for semiconductor devices. The first shield lines 25 and the second shield lines 45 may be electrically connected through the third pad part 27 and the fourth pad part 47. Thus, even if the first shield lines 25 and the second shield lines 45 are not in direct contact with each other, the second shield lines 45 may be electrically connected through the fourth pad part 47, the third pad part 27, and the first shield lines 25 to a ground circuit formed on the first substrate 11. Accordingly, it may be possible to provide a semiconductor device with improved operating stability.

FIG. 8 illustrates a cross-sectional view showing a semiconductor device according to some embodiments of the present inventive concepts.

Referring to FIG. 8, the second semiconductor chip 30 may include neither the third spacer patterns 43 nor the fourth spacer patterns 46. The first pad part 21 of the first pads 20 may be in contact with the first dielectric layer 13. The first shield lines 25 may be in contact with the first dielectric layer 13. The first spacer patterns 23 and the second spacer patterns 26 may be in contact with the bottom surface of the sixth sub-dielectric layer 36 included in the second semiconductor chip 30.

In some embodiments, differently from that shown, the second semiconductor chip 30 may include the third spacer patterns 43 and the fourth spacer patterns 46, and the first semiconductor chip 10 may include neither the first spacer patterns 23 nor the second spacer patterns 26. In this case, the second pad part 41 of the second pads 40 may be in contact with the second dielectric layer 33. The second shield lines 45 may be in contact with the second dielectric layer 33. The third spacer patterns 43 and the fourth spacer patterns 46 may be in contact with the top surface of the third sub-dielectric layer 16 included in the first semiconductor chip 10.

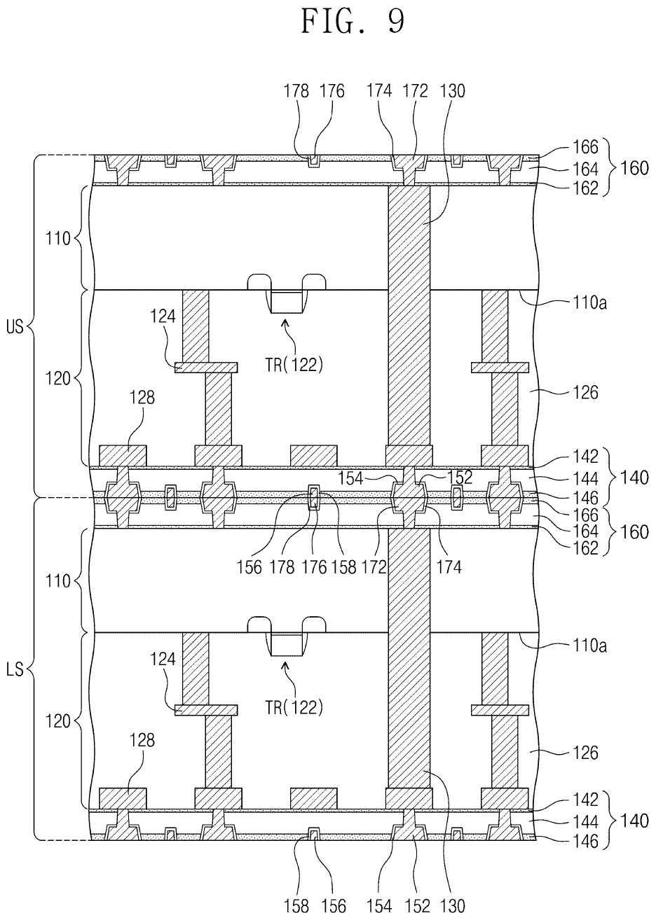

FIG. 9 illustrates a cross-sectional view showing a semiconductor device according to some embodiments of the present inventive concepts.

Referring to FIG. 9, there may be provided a lower structure LS and an upper structure US stacked on the lower structure LS.

Each of the lower and upper structures LS and US may include a semiconductor substrate 110, a circuit layer 120, a via 130, a lower protection layer 140, and an upper protection layer 160. For example, each of the lower and upper structures LS and US may correspond to one semiconductor die. The lower structure LS and the upper semiconductor substrate US may respectively correspond to the first semiconductor chip 10 and the second semiconductor chip 30 discussed with reference to FIG. 1.

The semiconductor substrate 110 may be provided. The semiconductor substrate 110 may correspond to the first substrate 11 discussed with reference to FIG. 1. The semiconductor substrate 110 may have a front surface 110a and a rear surface that are opposite to each other. The front surface 110a of the semiconductor substrate 110 may be defined to refer to a surface on which semiconductor elements are mounted or wiring lines and pads are formed, and the rear surface of the semiconductor substrate 110 may be defined to refer to a surface opposite to the front surface.

The circuit layer 120 may include a semiconductor element 122 and a device wiring part 124. The circuit layer 120 may correspond to the first circuit layer 12 discussed with reference to FIG. 1. The semiconductor element 122 may include at least one transistor TR provided on the front surface 110a of the semiconductor substrate 110.

The front surface 110a of the semiconductor substrate 110 may be covered with a device interlayer dielectric layer 126. The device interlayer dielectric layer 126 may bury the semiconductor element 122.

The device interlayer dielectric layer 126 may be provided therein with the device wiring part 124 connected to the transistor TR. The device wiring part 124 may include wiring patterns for horizontal wiring and connection contacts for vertical wiring. The wiring patterns may include a portion (referred to as an under-pad pattern 128) exposed on a bottom surface of the device interlayer dielectric layer 126. For example, a portion of the under-pad pattern 128 may be connected to the semiconductor element 122.

The via 130 may vertically penetrate the semiconductor substrate 110 and the device interlayer dielectric layer 126 to come into connection with a top surface of a portion of the under-pad pattern 128. The via 130 may vertically penetrate the device interlayer dielectric layer 126 and the semiconductor substrate 110 to be exposed on the rear surface of the semiconductor substrate 110.

The lower protection layer 140 may be disposed on the device interlayer dielectric layer 126. The lower protection layer 140 may correspond to the first dielectric layer 13 or the second dielectric layer 33 discussed with reference to FIG. 1. For example, the lower protection layer 140 may include a first sub-dielectric layer 142, a second sub-dielectric layer 144, and a third sub-dielectric layer 146 that are stacked on the bottom surface of the device interlayer dielectric layer 126.

The lower protection layer 140 may be provided therein with lower pads 152, first spacer patterns 154, lower shield lines 156, and second spacer patterns 158. The lower pad 152, the first spacer pattern 154, the lower shield line 156, and the second spacer pattern 158 may respectively correspond to the first pad 20, the first spacer pattern 23, the first shield line 25, and the second spacer pattern 26 discussed with reference to FIG. 1, or may respectively correspond to the second pad 40, the third spacer pattern 43, the second shield line 45, and the fourth spacer pattern 46 discussed with reference to FIG. 1.

For example, the lower pad 152 may include a pad part and a via part that extends from the pad part and is coupled to the under-pad pattern 128, the first spacer pattern 154 may cover lateral surfaces and a top surface of the pad part, and the via part may extend from the top surface of the pad part and penetrate the first spacer pattern 154. The second spacer patterns 158 may cover lateral and top surfaces of the lower shield lines 156.

The upper protection layer 160 may be disposed on the device interlayer dielectric layer 126. The upper protection layer 160 may correspond to the first dielectric layer 13 or the second dielectric layer 33 discussed with reference to FIG. 1. For example, the upper protection layer 160 may include a fourth sub-dielectric layer 162, a fifth sub-dielectric layer 164, and a sixth sub-dielectric layer 166 that are stacked on the rear surface of the semiconductor substrate 110.

The upper protection layer 160 may be provided therein with upper pads 172, the third spacer patterns 174, upper shield lines 176, and fourth spacer patterns 178. The upper pad 172, the third spacer pattern 174, the upper shield line 176, and the fourth spacer pattern 178 may respectively correspond to the first pad 20, the first spacer pattern 23, the first shield line 25, and the second spacer pattern 26 discussed with reference to FIG. 1, or may respectively correspond to the second pad 40, the third spacer pattern 43, the second shield line 45, and the fourth spacer pattern 46 discussed with reference to FIG. 1.

For example, the upper pad 172 may include a pad part and a via part that extends from the pad part and is coupled to the via 130, the third spacer pattern 174 may cover lateral and top surfaces of the pad part, and the via part may extend from the top surface of the pad part and penetrate the third spacer pattern 174. The fourth spacer patterns 178 may cover lateral and top surfaces of the upper shield lines 176.

The upper structure US may be disposed on the lower structure LS. The upper pads 172 and the upper shield lines 176 of the lower structure LS may be vertically aligned with the lower pads 152 and the lower shield lines 156 of the upper structure US. The lower structure LS and the upper structure US may be in contact with each other. The upper pads 172 and the upper shield lines 176 may be bonded to the lower pads 152 and the lower shield lines 156.

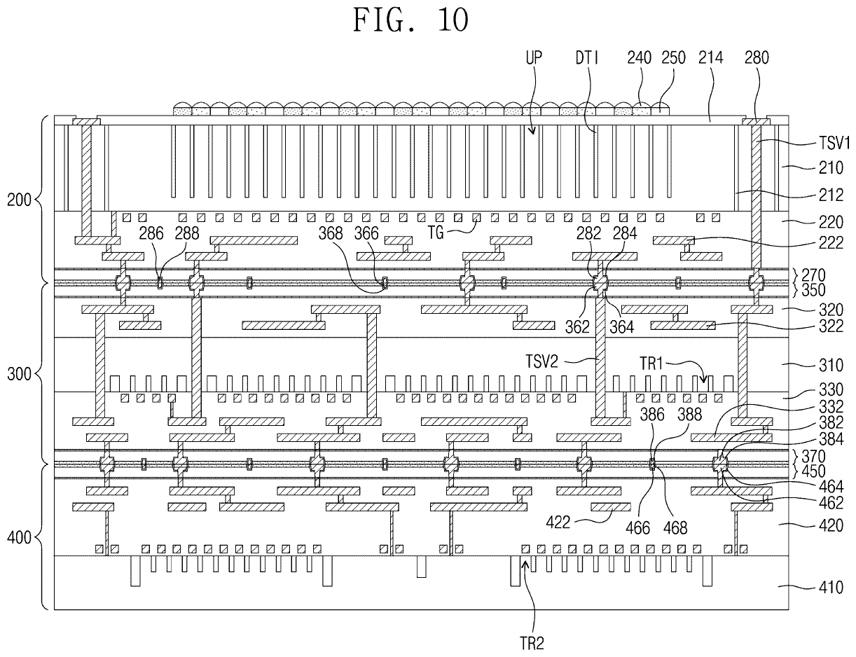

FIG. 10 illustrates a cross-sectional view showing a semiconductor device according to some embodiments of the present inventive concepts.

Referring to FIG. 10, a semiconductor package may include a first semiconductor chip 200, a second semiconductor chip 300 mounted below the first semiconductor chip 200, and a third semiconductor chip 400 mounted below the second semiconductor chip 300. The first, second, and third semiconductor chips 200, 300, and 400 may have different functions from each other. The first, second, and third semiconductor chips 200, 300, and 400 may have the same width. The first, second, and third semiconductor chips 200, 300, and 400 may have their sidewalls that are vertically aligned with each other. The first and second semiconductor chips 200 and 300 may be in contact with each other. The second and third semiconductor chips 300 and 400 may be in contact with each other.

The first semiconductor chip 100 may be, for example, an image sensor chip. The first semiconductor chip 200 may include a first semiconductor substrate 210 and a first interlayer dielectric layer 220 disposed on a bottom surface of the first semiconductor substrate 210.

The first semiconductor substrate 210 may include a semiconductor material. The first semiconductor substrate 210 may be provided therein with deep device isolation layers DTI that separate a plurality of photodiode regions UP from each other. A top surface of the first semiconductor substrate 210 may be covered with a first passivation layer 214. The first passivation layer 214 may include, for example, a silicon nitride (SiN) layer or a polyimide (PI) layer. The first passivation layer 214 may be provided thereon with a color filter 250 having colors corresponding to the photodiode regions IP. A microlens array 240 may be disposed on the color filter 250. The first semiconductor substrate 210 may be provided on an outer portion of the top surface thereof with first chip pads 280 spaced apart from the color filter 250. The first semiconductor substrate 210 may be provided therein with transfer gates TG for transferring charged generated from the photodiode regions UP.

A first interlayer dielectric layer 220 may cover the bottom surface of the first semiconductor substrate 210. First wiring patterns 222 may be disposed in the first interlayer dielectric layer 220. The first wiring patterns 222 may be electrically connected to second chip pads 282.

A first dielectric layer 270 may be disposed on a bottom surface of the first interlayer dielectric layer 220. The first dielectric layer 270 may correspond to the second dielectric layer 33 discussed with reference to FIG. 1. For example, the first dielectric layer 270 may include a plurality of sub-dielectric layers that are stacked on the bottom surface of the first interlayer dielectric layer 220.

The first dielectric layer 270 may be provided therein with second chip pads 282, first spacer patterns 284, first shield lines 286, and second spacer patterns 288. The second chip pad 282, the first spacer pattern 284, the first shield line 286, and the second spacer pattern 288 may respectively correspond to the second pad 40, the third spacer pattern 43, the second shield line 45, and the fourth spacer pattern 46 discussed with reference to FIG. 1. For example, the first spacer pattern 284 may cover lateral and top surfaces of a pad part of the second chip pad 282, and a via part of the second chip pad 282 may extend from the top surface of the pad part and penetrate the first spacer pattern 284. The second spacer patterns 288 may cover lateral and top surfaces of the first shield lines 286.

The first semiconductor substrate 210 may be provided therein with a first through via TSV1 that penetrates the first semiconductor substrate 210. The first through via TSV1 may penetrate a portion of the first interlayer dielectric layer 220 to come into electrical connection with the first wiring patterns 222 or the second chip pads 282. The first through via TSV1 may be coupled to the first chip pad 280.

The second semiconductor chip 300 may be, for example, a logic chip for operating the first semiconductor chip 100. Alternatively, the first semiconductor chip 200 and the second semiconductor chip 300 may constitute one image sensor chip. For example, the first semiconductor chip 200 and the second semiconductor chip 300 may correspond to chiplets of the one image sensor chip. The present inventive concepts, however, are not limited thereto, and a configuration of the first semiconductor chip 200 and the second semiconductor chip 300 may be variously provided as desired.

The second semiconductor chip 300 may include a second semiconductor substrate 310, a second interlayer dielectric layer 320 on the second semiconductor substrate 310, and a third interlayer dielectric layer 330 below the second semiconductor substrate 310.

The second semiconductor substrate 310 may include a semiconductor material. A plurality of first transistors TR1 may be disposed on a bottom surface of the second semiconductor substrate 310. The first transistors TR1 may include logic transistors. For example, the logic transistors may include a reset transistor, a selection transistor, and a drive transistor.

The second interlayer dielectric layer 320 may cover a top surface of the second semiconductor substrate 310. Second wiring patterns 322 may be disposed in the second interlayer dielectric layer 320. The second wiring patterns 322 may be electrically connected to third chip pads 362.

A second dielectric layer 350 may be disposed on a top surface of the second interlayer dielectric layer 320. The second dielectric layer 350 may correspond to the first dielectric layer 13 discussed with reference to FIG. 1. For example, the second dielectric layer 350 may include a plurality of sub-dielectric layers stacked on the top surface of the second interlayer dielectric layer 320.

The second dielectric layer 350 may be provided therein with third chip pads 362, third spacer patterns 364, second shield lines 366, and fourth spacer patterns 368. The third chip pad 362, the third spacer pattern 364, the second shield line 366, and the fourth spacer pattern 368 may respectively correspond to the first pad 20, the first spacer pattern 23, the first shield line 25, and the second spacer pattern 26 discussed with reference to FIG. 1. For example, the third spacer pattern 364 may cover lateral and bottom surfaces of a pad part of the third chip pad 362, and a via part of the third chip pad 362 may extend from the bottom surface of the pad part and penetrate the third spacer pattern 364. The fourth spacer patterns 368 may cover lateral and bottom surfaces of the second shield lines 366.

A third interlayer dielectric layer 330 may cover the bottom surface of the second semiconductor substrate 310. Third wiring patterns 332 may be disposed in the third interlayer dielectric layer 330. The third wiring patterns 332 may be electrically connected to the first transistors TR1 and fourth chip pads 382.

A third dielectric layer 370 may be disposed on a bottom surface of the third interlayer dielectric layer 330. The third dielectric layer 370 may correspond to the second dielectric layer 33 discussed with reference to FIG. 1. For example, the third dielectric layer 370 may include a plurality of sub-dielectric layers that are stacked on the bottom surface of the third interlayer dielectric layer 330.

The third dielectric layer 370 may be provided therein with fourth chip pads 382, fifth spacer patterns 384, third shield lines 386, and sixth spacer patterns 388. The fourth chip pad 382, the fifth spacer pattern 384, the third shield line 386, and the sixth spacer pattern 388 may respectively correspond to the second pad 40, the third spacer pattern 43, the second shield line 45, and the fourth spacer pattern 46 discussed with reference to FIG. 1. For example, the fifth spacer pattern 384 may cover lateral and top surfaces of a pad part of the fourth chip pad 382, and a via part of the fourth chip pad 382 may extend from the top surface of the pad part and penetrate the fifth spacer pattern 384. The sixth spacer patterns 388 may cover lateral and top surfaces of the third shield lines 386.

The second semiconductor substrate 310 may be provided therein with a second through via TSV2 that penetrates the second semiconductor substrate 310. The second through via TSV2 may penetrate a portion of the second interlayer dielectric layer 320 to come into electrical connection with the second wiring patterns 322 or the third chip pads 362. The second through via TSV2 may penetrate a portion of the third interlayer dielectric layer 330 to come into electrical connection with the third wiring patterns 332. The first transistors TR1 may be electrically connected to the first semiconductor chip 200 through a connection contact, the third wiring patterns 332, the second through via TSV2, and the third chip pads 362.

The second semiconductor chip 300 may be mounted on the first semiconductor chip 200. For example, an intermetallic hybrid bonding may be made between the third chip pads 362 of the second semiconductor chip 300 and the second chip pads 282 of the first semiconductor chip 200.

The third semiconductor chip 400 may be, for example, a memory chip for storing data produced from the second semiconductor chip 300. For example, the third semiconductor chip 400 may be a DRAM chip. The present inventive concepts, however, are not limited thereto, and a configuration of the third semiconductor chip 400 may be variously provided as desired.

The third semiconductor chip 400 may include a third semiconductor substrate 410 and a fourth interlayer dielectric layer 420 on the third semiconductor substrate 410.

The third semiconductor substrate 410 may include a semiconductor material. A plurality of second transistors TR2 may be disposed on a top surface of the third semiconductor substrate 410. The second transistors TR2 may include memory transistors.

The fourth interlayer dielectric layer 420 may cover the top surface of the third semiconductor substrate 410. Fourth wiring patterns 422 may be disposed in the fourth interlayer dielectric layer 420. The fourth wiring patterns 422 may be electrically connected to fifth chip pads 462.

A fourth dielectric layer 450 may be disposed on a top surface of the fourth interlayer dielectric layer 420. The fourth dielectric layer 450 may correspond to the first dielectric layer 13 discussed with reference to FIG. 1. For example, the fourth dielectric layer 450 may include a plurality of sub-dielectric layers stacked on the top surface of the fourth interlayer dielectric layer 420.

The fourth dielectric layer 450 may be provided therein with fifth chip pads 462, seventh spacer patterns 464, fourth shield lines 466, and eighth spacer patterns 468. The fifth chip pad 462, the seventh spacer pattern 464, the fourth shield line 466, and the eighth spacer pattern 468 may respectively correspond to the first pad 20, the first spacer pattern 23, the first shield line 25, and the second spacer pattern 26 discussed with reference to FIG. 1. For example, the seventh spacer pattern 464 may cover lateral and bottom surfaces of a pad part of the fifth chip pad 462, and a via part of the fifth chip pad 462 may extend from the bottom surface of the pad part and penetrate the seventh spacer pattern 464. The eighth spacer patterns 468 may cover lateral and bottom surfaces of the fourth shield lines 466.

The third semiconductor chip 400 may be mounted on the second semiconductor chip 300. For example, an intermetallic hybrid bonding may be made between the fifth chip pads 462 of the third semiconductor chip 400 and the fourth chip pads 382 of the second semiconductor chip 300.

FIGS. 11 to 18 illustrate cross-sectional views showing a method of fabricating a semiconductor device according to some embodiments of the present inventive concepts.

Referring to FIG. 11, a first substrate 11 may be provided. An ordinary process may be performed to form a first circuit layer 12 on the first substrate 11. The first circuit layer 12 may have a first connection line 17 for connecting the first substrate 11 to first pads 20.

Dielectric materials may be sequentially deposited on the first circuit layer 12, thereby forming a first dielectric layer 13. For example, a nitride layer, an oxide layer, and a nitride layer may be sequentially stacked on the first circuit layer 12 to form a first sub-dielectric layer 14, a second sub-dielectric layer 15, and a third sub-dielectric layer 16. The first dielectric layer 13 may cover the first circuit layer 12. The first sub-dielectric layer 14 and the third sub-dielectric layer 16 may be formed of a material having an etch selectivity with respect to the second sub-dielectric layer 15.

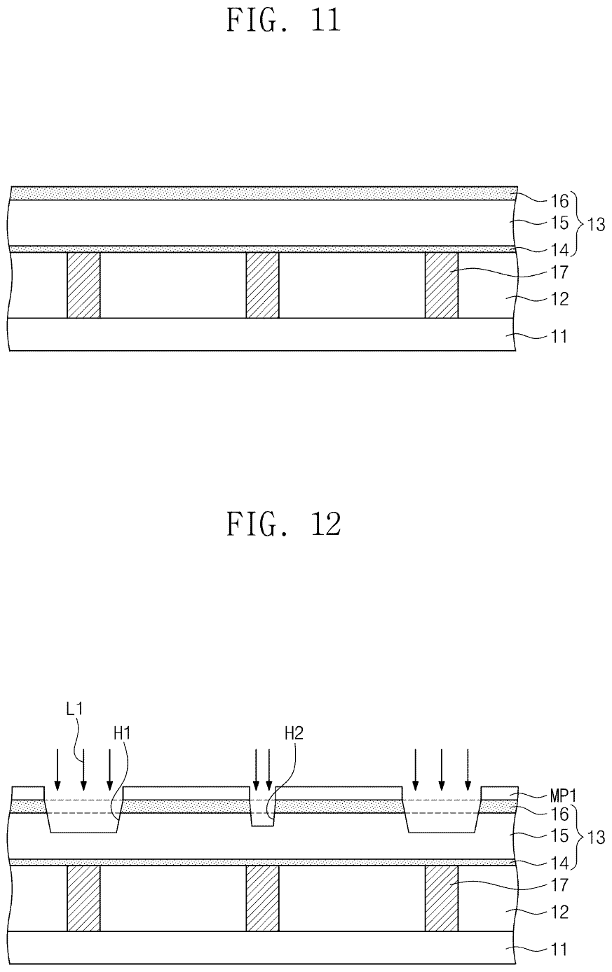

Referring to FIG. 12, a first patterning process may be performed on the first dielectric layer 13. The first patterning process may form a first hole H1 and a second hole H2 in the first dielectric layer 13. For example, a first mask pattern MP1 may be formed on the first dielectric layer 13. The first mask pattern MP1 may define a region where first pads 20 will be formed in a subsequent process and a region where first shield lines 25 will be formed in a subsequent process. The first mask pattern MP1 may be obtained by forming a photosensitive material layer on the first dielectric layer 13, and then allowing the photosensitive material layer to undergo a first exposure and development process.

A first light L1 used in the first patterning process, or the first exposure and development process, may be a ray generated from a KrF light source. In this case, the first light L1 may have a wavelength of about or exactly 248 nanometers. Afterwards, the first mask pattern MP1 may be used to etch the first dielectric layer 13. The first patterning process may be performed by using the first mask pattern MP1 as an etch mask. The first and second holes H1 and H2 may have their bottom surfaces located at a level higher than that of a bottom surface of the first sub-dielectric layer 14. The second hole H2 may be disposed on one side of the first hole H1, and when viewed in plan, may extend in one direction. For example, the second hole H2 may be formed as a trench shape. A width of the second hole H2 formed as a linear shape may be less than that of the first hole H1.

A minimum width of the second hole H2 may depend on the wavelength of the first light L1. For example, the second hole H2 may have a minimum width of equal to or greater than about or exactly 140 nanometers up to about or exactly 500 nanometers. To cause a reduction in width of the second hole H2, it may be required that the first patterning process be performed using a light whose wavelength is shorter than that of the first light L1, and this case may increase a process unit price or manufacturing cost.

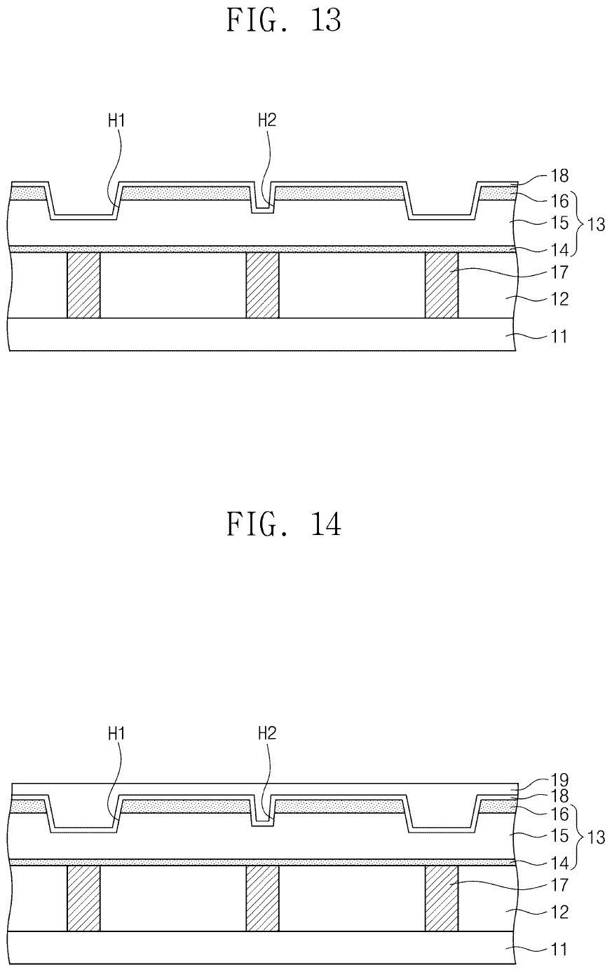

Referring to FIG. 13, the first mask pattern MP1 may be removed. Thus, a top surface of the first dielectric layer 13 may be exposed.

A spacer layer 18 may be formed on the first dielectric layer 13. For example, a dielectric layer may be coated or deposited to form the spacer layer 18 on the first dielectric layer 13. The spacer layer 18 may include a material having an etch selectivity with respect to the third sub-dielectric layer 16. The spacer layer 18 may include, for example, silicon oxide (SiO) or tetraethylorthosilicate (TEOS). The spacer layer 18 may conformally cover a top surface of the third sub-dielectric layer 16, inner lateral and bottom surfaces of the first hole H1, and inner lateral and bottom surfaces of the second hole H2. The spacer layer 18 may have a thickness of about or exactly 10 nanometers to about or exactly 100 nanometers.

As the spacer layer 18 is coated in the first hole H1 and the second hole H2, the first hole H1 and the second hole H2 may have their reduced widths of unoccupied spaces thereof. Thus, even though a short-wavelength light is not used, first pads 20 and first shield lines 25 may be formed to have their fine patterns. For example, it may be possible to fabricate a semiconductor device with high integration and reduced process unit price or manufacturing cost. The second hole H2 may have a width of about or exactly 100 nanometers to about or exactly 140 nanometers.

Referring to FIG. 14, a sacrificial layer 19 may be formed on the spacer layer 18. A dielectric layer including a planarization material may be deposited or coated to form the sacrificial layer 19 on the spacer layer 18. The planarization material may include an organic planarization material such as near frictionless carbon (NFC) or any other suitable material such as spin-on-carbon (SOC) or spin-on-hardmask (SOH). The sacrificial layer 19 may cover the top surface of the first dielectric layer 13, while filling the first hole H1 and the second hole H2. A top surface of the sacrificial layer 19 may be flat or substantially flat.

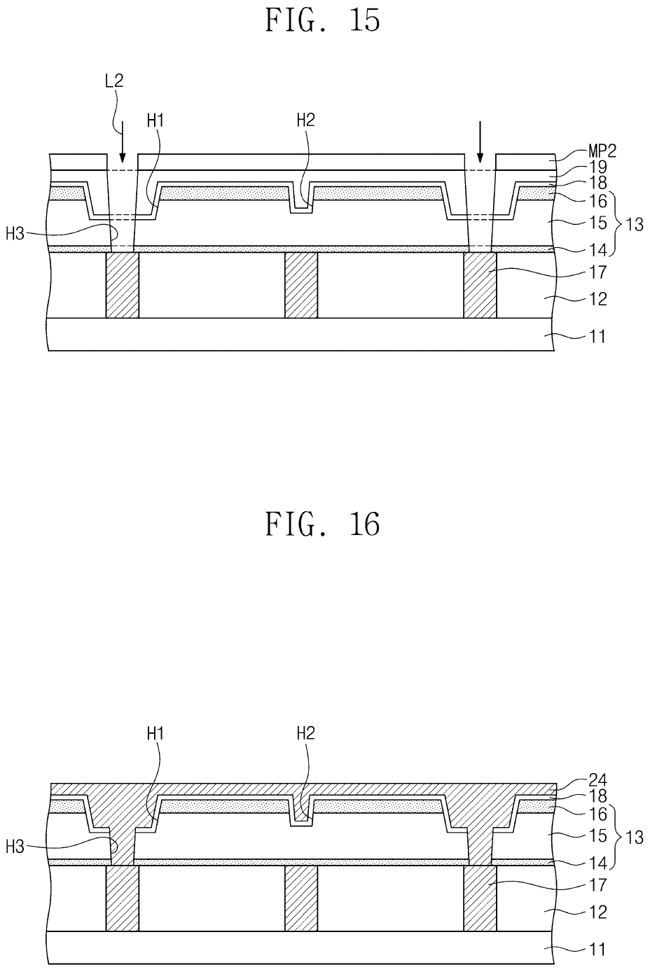

Referring to FIG. 15, a second patterning process may be performed on the sacrificial layer 19. The second patterning process may form a third hole H3 in the sacrificial layer 19. The third hole H3 may be positioned inside the first hole H1. In this case, the third hole H3 may penetrate the bottom surface of the first hole H1. For example, a second mask pattern MP2 may be formed on the sacrificial layer 19. The second mask pattern MP2 may define a region where via parts of first pads 20 will be formed in a process which will be described below. The second mask pattern MP2 may be obtained by forming a photosensitive material layer on the sacrificial layer 19, and then allowing the photosensitive material layer to undergo a second exposure and development process.

A second light L2 used in the second patterning process, or the second exposure and development process, may have a wavelength less than the first light L1 used in the first patterning process, or the first exposure and development process. The second light L2 may be a ray generated from an ArF light source/In this case, the second light L2 may have a wavelength of about or exactly 193 nanometers.

After that, the second mask pattern MP2 may be used to etch the sacrificial layer 19, the spacer layer 18, the second sub-dielectric layer 15, and the first sub-dielectric layer 14. The second patterning process may be performed by using the second mask pattern MP2 as an etch mask. The first circuit layer 12 or the first connection line 17 may be exposed through a bottom surface of the third hole H3.

Referring to FIG. 16, the second mask pattern MP2 and sacrificial layer 19 may be removed. Thus, the spacer layer 18 may be exposed.

A conductive layer 24 may be formed on the spacer layer 18. An electroplating process may be performed to form the conductive layer 24. In this case, the conductive layer 24 may be formed using a seed, such as the first connection line 17 or a portion of a wiring line in the first circuit layer 12 exposed by the third hole H3. Alternatively, the conductive layer 24 may be formed by forming a seed layer that conformally covers the first dielectric layer 13 and the spacer layer 18, and then using the seed layer as a seed.

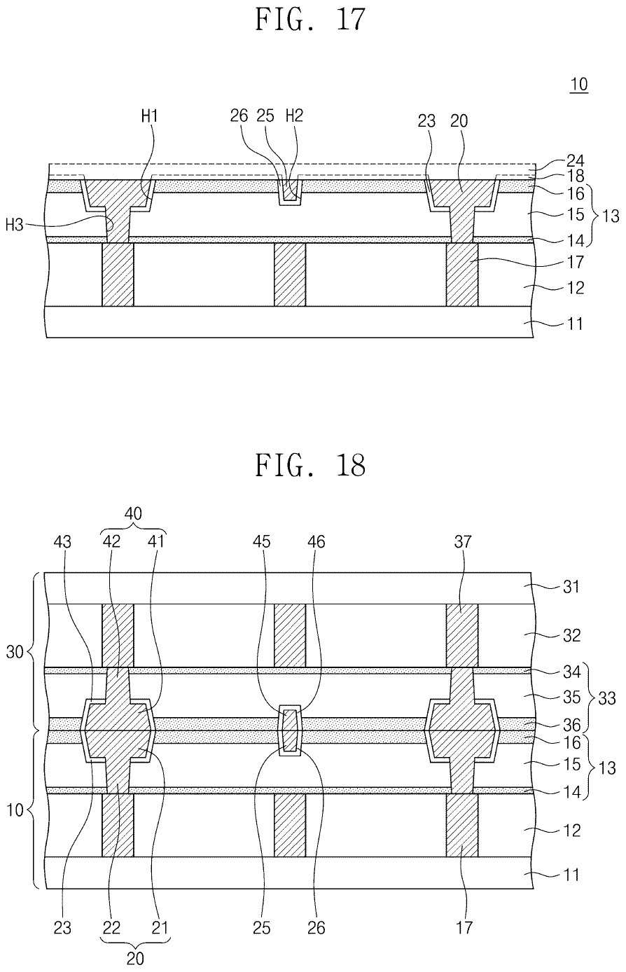

Referring to FIG. 17, a thinning process may be performed on the conductive layer 24. The thinning process may continue until a top surface of the spacer layer 18 is exposed. According to some embodiments, the thinning process may be continuously performed to remove a portion of the spacer layer 18. The thinning process may be executed until the top surface of the first dielectric layer 13 is exposed. The thinning process may remove a portion of the conductive layer 24 positioned on the top surface of the first dielectric layer 13, and first pads 20 and first shield lines 25 may be formed separated from each other. For example, the conductive layer 24 filling the first hole H1 and the second hole H2 may constitute the first pad 20, and the conductive layer 24 filling the second hole H2 may constitute the first shield line 25. The first shield line 25, or the conductive layer 24 positioned in the second hole H2, may have a width of about or exactly 100 nanometers to about or exactly 140 nanometers.

Through the processes above, a first semiconductor chip 10 may be manufactured.

Referring to FIG. 18, a second semiconductor chip 30 may be manufactured. The manufacturing process of the second semiconductor chip 30 may be the same or substantially the same as or similar to that of the first semiconductor chip 10 discussed with reference to FIGS. 11 to 17.

The second semiconductor chip 30 may be provided on the first semiconductor chip 10. For example, the second semiconductor chip 30 may be placed on the first semiconductor chip 10 to vertically align the first pads 20 with the second pads 40.

After that, the first semiconductor chip 10 and the second semiconductor chip 30 may be in contact with each other. The top surface of the first dielectric layer 13 included in the first semiconductor chip 10 may be in contact with a bottom surface of the second dielectric layer 33 included in the second semiconductor chip 30. Top surfaces of the first pads 20 included in the first semiconductor chip 10 may be in contact with bottom surfaces of the second pads 40 included in the second semiconductor chip 30.

A heat treatment process may be performed on the first semiconductor chip 10 and the second semiconductor chip 30. The heat treatment process may bond the first pads 20 of the first semiconductor chip 10 to the second pads 40 of the second semiconductor chip 30. When the first shield line 25 of the first semiconductor chip 10 is in contact with the second shield line 45 of the second semiconductor chip 30, the heat treatment process may bond the first shield line 25 to the second shield line 45. The first pad 20 and the second pad 40 may be naturally bonded to each other. For example, the first pad 20 and the second pad 40 may be formed of the same material (e.g., copper (Cu)), and may be bonded to each other by an intermetallic hybrid bonding process resulting from surface activation at an interface between the first pad 20 and the second pad 40 that are in contact with each other.

In this description, the concept of individual chips may be defined to indicate stack structures formed from different semiconductor wafers. Although a boundary between individual chips is not clearly observed depending on a bonding form and material between the chips, the concept of individual chips formed from different semiconductor wafers is not excluded even in such a stacked structure.

In a semiconductor device according to some embodiments of the present inventive concepts, pads and shield lines may be provided in holes or trenches formed in a dielectric layer of a semiconductor chip, and a spacer pattern may be provided in the holes or the trenches to provide pads and shield lines having their widths. For example, line-shape shield lines may be provided to have their fine line-widths. As a result, the semiconductor device may improve in integration.

In a method of fabricating a semiconductor device according to some embodiments of the present inventive concepts, a spacer layer may be coated in holes or trenches formed in a dielectric layer of a semiconductor chip, and thus the holes or the trenches may have their reduced widths of unoccupied spaces thereof. Therefore, even though a short-wavelength light is not used, pads and shield lines may be formed to have their fine patterns. It may thus be possible to fabricate a semiconductor device with high integration and reduced process unit price.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

Although the present invention has been described in connection with some embodiments of the present inventive concepts illustrated in the accompanying drawings, it will be understood by one of ordinary skill in the art that variations in form and detail may be made therein without departing from the spirit and essential feature of the present inventive concepts. The above disclosed embodiments should thus be considered illustrative and not restrictive.

What is claimed is

1. A semiconductor device, comprising:
a first semiconductor chip; and
a second semiconductor chip on the first semiconductor chip,
the first semiconductor chip including
a first semiconductor substrate;
a first dielectric layer on the first semiconductor substrate;
a first pad part exposed on a top surface of the first dielectric layer;
a first via part extending from a bottom surface of the first pad part and coupled to the first semiconductor substrate, the first via part having a width less than a width of the first pad part;
a first spacer pattern between the first dielectric layer, a lateral surface of the first pad part, and the bottom surface of the first pad part;
a first shield line horizontally spaced apart from the first pad part and extending into the first dielectric layer from the top surface of the first dielectric layer; and
a second spacer pattern between the first dielectric layer, a lateral surface of the first shield line, and a bottom surface of the first shield line,
on a contact surface between the first semiconductor chip and the second semiconductor chip, the first pad part of the first semiconductor chip and a second pad part of the second semiconductor chip being in direct contact with each other to constitute a single unitary piece.

2. The semiconductor device of claim 1, wherein the bottom surface of the first pad part is closer than the bottom surface of the first shield line to the first semiconductor substrate.

3. The semiconductor device of claim 1, wherein, on the bottom surface of the first pad part, the first via part penetrates the first spacer pattern to couple with the first semiconductor substrate.

4. The semiconductor device of claim 1, wherein
when viewed in plan, the first shield line has a linear shape extending in one direction on one side of the first pad part, and
a width of the first shield line is 100 nanometers to 140 nanometers.

5. The semiconductor device of claim 1, wherein a thickness of the first spacer pattern is 10 nanometers to 100 nanometers.

6. The semiconductor device of claim 1, wherein
the first dielectric layer comprises:
a first sub-dielectric layer; and
a second sub-dielectric layer on the first sub-dielectric layer, and
the second sub-dielectric layer and the first spacer pattern comprise different dielectric materials from each other.

7. The semiconductor device of claim 1, wherein
the first pad part has a tapered cross-section and the width of the first pad part decreases with decreasing distance from the first semiconductor substrate, and
the first shield line has a tapered cross-section and a width of the first shield line decreases with decreasing distance from the first semiconductor substrate.

8. The semiconductor device of claim 1, wherein the first pad part and the first via part are further included in the single unitary piece.

9. The semiconductor device of claim 1, wherein the second semiconductor chip comprises:
a second semiconductor substrate;
a second dielectric layer on the second semiconductor substrate;
the second pad part exposed on a bottom surface of the second dielectric layer;
a second via part extending from a top surface of the second pad part and coupled to the second semiconductor substrate, the second via part having a width less than a width of the second pad part;
a third spacer pattern between the second dielectric layer, a lateral surface of the second pad part, and the top surface of the second pad part;
a second shield line horizontally spaced apart from the second pad part and extending into the second dielectric layer from the bottom surface of the second dielectric layer; and
a fourth spacer pattern between the second dielectric layer, a lateral surface of the second shield line, and a bottom surface of the second shield line.

10. The semiconductor device of claim 9, wherein
the first shield line and the second shield line are vertically aligned with each other, and
on the contact surface between the first semiconductor chip and the second semiconductor chip, the first shield line and the second shield line are in direct contact with each other to constitute a single shield unitary piece.

11. The semiconductor device of claim 9, wherein
the first shield line and the second shield line are horizontally shifted from each other, and
on the contact surface between the first semiconductor chip and the second semiconductor chip, the first shield line is in contact with the bottom surface of the second dielectric layer, and the second shield line is in contact with the top surface of the first dielectric layer.

12. A semiconductor device, comprising:
a first semiconductor chip;
a second semiconductor chip on the first semiconductor chip;
a color filter array on the second semiconductor chip; and
a microlens array on the color filter array,
the first semiconductor chip including
a first dielectric layer on a top surface of the first semiconductor chip;
a first pad part exposed on a top surface of the first dielectric layer;
a first via part extending into the first dielectric layer from a bottom surface of the first pad part;
a first shield line horizontally spaced apart from the first pad part and extending into the first dielectric layer from the top surface of the first dielectric layer; and
a first spacer pattern covering a lateral surface of the first shield line and a bottom surface of the first shield line,
the second semiconductor chip including
a second dielectric layer on a bottom surface of the second semiconductor chip;
a second pad part exposed on a bottom surface of the second dielectric layer;
a second shield line horizontally spaced apart from the second pad part and extending into the second dielectric layer from the bottom surface of the second dielectric layer; and
a second spacer pattern covering a lateral surface of the second shield line and a top surface of the second shield line,
on a contact surface between the first semiconductor chip and the second semiconductor chip, the first pad part of the first semiconductor chip and the second pad part of the second semiconductor chip are in direct contact with each other to constitute a single unitary piece.

13. The semiconductor device of claim 12, wherein
the first semiconductor chip further comprises a third spacer pattern covering the bottom surface of the first pad part and a lateral surface of the first pad part, and
on the bottom surface of the first pad part, the first via part penetrates the third spacer pattern to extend into the first dielectric layer.

14. The semiconductor device of claim 12, wherein the bottom surface of the first pad part is farther than the bottom surface of the first shield line from the top surface of the first semiconductor chip.

15. The semiconductor device of claim 12, wherein
when viewed in plan, the first shield line has a linear shape extending in one direction on one side of the first pad part, and
a width of the first shield line is 100 nanometers to 140 nanometers.

16. The semiconductor device of claim 12, wherein a thickness of the first spacer pattern is 10 nanometers to 100 nanometers.

17. The semiconductor device of claim 12, wherein
the first shield line and the second shield line are horizontally shifted from each other, and
on the contact surface between the first semiconductor chip and the second semiconductor chip, the first shield line is in contact with the bottom surface of the second dielectric layer, and the second shield line is in contact with the top surface of the first dielectric layer.

18. A method of fabricating a semiconductor device, the method comprising:
sequentially stacking a first dielectric layer and a second dielectric layer on a semiconductor substrate;
allowing the second dielectric layer and the first dielectric layer to undergo a first patterning process to define a first hole and a trench, a bottom surface of the first hole and a bottom surface of the trench being at a level higher than a level of a bottom surface of the first dielectric layer;
forming a spacer layer covering a top surface of the second dielectric layer, an inner lateral surface of the first hole, the bottom surface of the first hole, an inner lateral surface of the trench, and the bottom surface of the trench;
forming on the spacer layer a sacrificial layer filling the first hole and the trench and covering the top surface of the second dielectric layer;
allowing the sacrificial layer, the spacer layer, and the first dielectric layer to undergo a second patterning process to define a second hole, the second hole being inside the first hole;
removing the sacrificial layer;
forming, on the spacer layer, a conductive layer filling the first hole, the second hole, and the trench and covers the top surface of the second dielectric layer; and
allowing the conductive layer to undergo a thinning process to expose the top surface of the second dielectric layer,
a wavelength of a light source used in the first patterning process being greater than a wavelength of a light source used in the second patterning process.

19. The method of claim 18, wherein
the first patterning process uses a KrF light source, and
the second patterning process uses an ArF light source.

20. The method of claim 18, wherein
a thickness of the spacer layer is 10 nanometers to 100 nanometers,
on the spacer layer, a portion of the conductive layer fills the trench, and
a width of the portion of the conductive layer in the trench is 100 nanometers to 140 nanometers.
